(19) United States
(12) Patent Application Publication
(10) Pub. No.: US 2020/0161492 A1
(43) Pub. Date: May 21, 2020

(54) Light distribution plate for uniform irradiance of compact photovoltaic arrays

(71) Applicant: National Technology & Engineering Solutions of Sandia, LLC, Albuquerque, NM (US)

(72) Inventors: Gregory A. Vawter, Corrales, NM (US); Junoh Choi, Albuquerque, NM (US); Erik J. Skogen, Tijeras, NM (US); Richard N. Shagam, Albuquerque, NM (US)

(21) Appl. No.: 16/686,541

(22) Filed: Nov. 18, 2019

Related U.S. Application Data
(60) Provisional application No. 62/769,376, filed on Nov. 19, 2018.

(51) Int. Cl. H01L 31/054; F21V 8/00

(52) U.S. Cl. CPC H01L 31/0543; H01L 31/0547; G02B 6/0031; G02B 6/003; G02B 6/0073

(57) ABSTRACT

A light distribution plate can be edge-illuminated by fiber optic light sources. The input-coupled travels in the plate by total internal reflection and is scattered out of the top surface of the plate by micro-optical structures on the bottom surface. The light distribution plate can provide uniform irradiation of, for example, compact photovoltaic arrays on the top surface.

### CROSS-REFERENCE TO RELATED APPLICATIONS

This application claims the benefit of U.S. Provisional Application No. 62/769,376, filed Nov. 19, 2018, which is incorporated herein by reference. This application is related to U.S. application Ser. No. 16/366,942, filed Mar. 27, 2019, which is incorporated herein by reference.

### STATEMENT OF GOVERNMENT INTEREST

This invention was made with Government support under Contract No. DE-NA0003525 awarded by the United States Department of Energy/National Nuclear Security Administration. The Government has certain rights in the invention.

### FIELD OF THE INVENTION

The present invention relates to power-over-fiber systems and, in particular, to a light distribution plate for uniform irradiance of compact photovoltaic arrays.

### BACKGROUND OF THE INVENTION

Power-over-fiber systems (also known as power-by-light systems) rely on the transmission of spectrally narrow bandwidth laser or light-emitting diode (LED) light via an optical fiber or free space (i.e., wireless) to a receiver, where it is converted back into electricity by a photovoltaic (PV) power converter designed to operate using the same or similar spectral bandwidth as the light source to supply an electrical load. These systems have the advantage of galvanically isolating the optical power supply from the PV power converter, since these subsystems are electrically disconnected from each other. This “optically remoted” power can then be immune to deleterious effects of static electricity build-up and discharge as well as mundane electrical surges on a system power bus. The use of a monochromatic or narrow spectral bandwidth light source enables the efficient conversion of light back into electricity using III-V semiconductor PV cells designed to operate with a source-matched spectral bandwidth and with high source intensities, unlike solar cell applications which suffer from efficiency losses due to the spectrally broadband nature of solar radiation.

The major components to be powered range from standard electronics packages, needing nominally 4V at 800 mA, to high-voltage elements requiring many-hundreds to thousands of volts. In all cases, optical power is transferred over optical fiber and illuminates a set of photovoltaic diodes arranged electrically in series and/or parallel to combine and deliver the needed voltage and current to the electrical load. However, some power-over-fiber systems require an extremely small and efficient means of transferring power to sub-systems optically. Owing to volume limitations, power bus systems require a package with as small a volume as possible. Previous systems have used photovoltaic illumination of arrays at normal incidence from optical fibers placed on a side-mounted header. This approach leads to unacceptably large overall size and does not address the problem of speckle from coherent laser sources.

The present invention uses photovoltaic illumination by a novel and improved configuration of an edge-illuminated light distribution plate.

### SUMMARY OF THE INVENTION

The present invention is directed to a light distribution plate that is optically transparent at an operational wavelength of input light, has an index of refraction higher than a surrounding medium, and has an optically transparent top surface, a bottom surface comprising a reflecting pattern of micro-optical structures, and at least one side edge, wherein the input light is coupled into the light distribution plate through an optically transparent side edge, the input-coupled light travels in the light distribution plate by total internal reflection, and at least a portion of the input-coupled light is reflected, scattered, or diffracted by the micro-optical structures on the bottom surface and coupled out of the top surface. At least one optical fiber can couple light into the optically transparent side edge. The light distribution plate can comprise a flat plate, slab, cuboid, or rectangular prism, or it can comprise a wedged plate having a bottom surface that is tilted with respect to the top surface. The light distribution plate can comprise a polymer, fused silica, glass, or any crystalline or amorphous material that has a high transmission in the spectral bandwidth of operation. The reflecting micro-optical structures can comprise prisms, lenses, grooves, dots, dimples, spherical or aspherical elements, or surface features that scatter or diffract reflected light. The reflecting patterned surface can comprise an array of micro-optical structures that are of uniform size, depth, shape, and spacing. Alternatively, the reflecting micro-optical structures can have a size, depth, shape, or spacing that is varied to provide a desired irradiation pattern at the top surface of the light distribution plate. The array of micro-optical elements can have a periodic pattern in a longitudinal direction. The pitch of the periodic pattern can be coarser close to the optically transparent side edge of the input-coupled light than at the far edge. The input-coupled light can comprise spectrally narrow bandwidth light, such as light from a laser or a light-emitting diode, or broadband. An ultrasonic transducer can introduce a time-varying disturbance into the at least one optical fiber to reduce speckle in input-coupled laser light. An array of photovoltaic diodes can be disposed on the top surface of the light distribution plate that are illuminated by the output-coupled light. The system can further comprise a transparent spacer plate disposed between the light distribution plate and the photovoltaic array.

### BRIEF DESCRIPTION OF THE DRAWINGS

The detailed description will refer to the following drawings, wherein like elements are referred to by like numbers.

FIG. 1 is a side-view schematic illustration of a light distribution plate (LDP) comprising an edge-illuminated light guide with optical fiber light inputs that uniformly irradiates a photovoltaic (PV) diode array on the top surface of the LDP. Illumination of the PV diode array is shown as through a transparent substrate and onto the bonded side of the PV diode array.

FIG. 2A is a schematic illustration of a flat LDP with parallel cylindrical grooves on the bottom surface and edges coated with a high reflectance coating.

FIG. 2B shows the computed intensity distribution of the flat LDP at the top output surface.

FIG. 3A is a schematic illustration of an LDP comprising a flat plate with a uniform dimpled etch pattern on the bottom surface. FIG. 3B shows the computed intensity distribution of the uniform etch pattern LDP at the top output surface.

FIG. 4A is a schematic illustration of an LDP comprising a tapered (wedged) plate. FIG. 4B shows the computed intensity distribution of the tapered LDP at the top output surface.

FIG. 5A is a schematic illustration of an LDP comprising a flat plate with a non-uniform etch pattern that varies longitudinally in the direction of the input light. FIG. 5B shows the computed intensity distribution of the non-uniform etch pattern LDP at the top output surface.

FIGS. 6A and 6B show line outs comparing the uniformity of irradiance of the LDP design shown in FIG. 3A and the LDP design shown in FIG. 5A, respectively.

### DETAILED DESCRIPTION OF THE INVENTION

For maximum efficiency, each diode in a series-connected chain of PV diodes must generate the same electrical current as the others (i.e., each of the diodes ideally behaves as an identical current source). Since the photocurrent of a PV diode is proportional to the light that is incident on the diode, if one diode of a series-connected chain receives a low light level, the entire series chain has a low current. Therefore, when a PV diode in a series-connected chain is poorly illuminated, the generated current will be reduced, limiting the overall current in the series PV diode chain. Therefore, it is highly desirable that an array of PV cells be uniformly irradiated given that the PV diodes in the series chain are nominally identical in size and shape.

The simplest method of delivering optical power to a PV array is using a direct irradiance pattern from a multimode fiber. The radiation pattern emitted from a multimode fiber has a Gaussian irradiance distribution. If, for example, a 5 mm diameter array is illuminated by an optical fiber with a numerical aperture (NA) of 0.22 at a fiber standoff distance of 11 mm, the irradiance at the edge of the PV array is only 5 percent of the central peak. With a Gaussian beam exiting a fiber and illuminating a series-connected PV array, the resulting current would be severely limited by the reduced irradiance of the PV diodes at the edges. Furthermore, front normal illumination of a 5 mm PV array at that standoff distance would require considerable space and a large form factor.

Uniform irradiance of a PV array with a smaller form factor is possible with edge-type backlight units similar to those developed for flat panel displays, e.g. flat panel computer monitors, cell phones, personal data assistants (PDAs, e.g. iPads®, and tablet computers), and LCD televisions. This display technology uses a thin, flat transparent light pipe, usually referred to as a ‘light-guide plate’ (LGP) that is edge illuminated, usually by a miniature compact fluorescent tube or a one-dimensional array of white-light LEDs. The LGP is “optically thick” (i.e., the plate has an index of refraction higher than the surrounding medium such that light is kept in the plate by total internal reflection), on the order of 100s of microns, and the light propagation is according to the rules of geometric optics. Owing to total internal reflection, light is confined to the flat volume of the LGP. However, the top and bottom flat surfaces can be combined with scattering structures that direct a fraction of the light out of the LGP. In large displays, the output-coupled light passes through an LCD modulator structure and on towards the observer.

The present invention expands on the LGP concept used in displays to provide a light distribution plate (LDP) suited for extremely uniform and efficient irradiance of very small (i.e., few-mm) size regions where uniformity of power and total optical efficiency are paramount and the angular distribution of light or viewing cone, important to the display industry, is not so important. In the present invention, edge illumination of an LDP can be provided by an array of multimode optical fibers illuminated by laser diodes or LEDs and the LCD structure is replaced by a PV array. Use of laser diodes and fiber optics enables higher optical power than can be obtained with single mode systems.

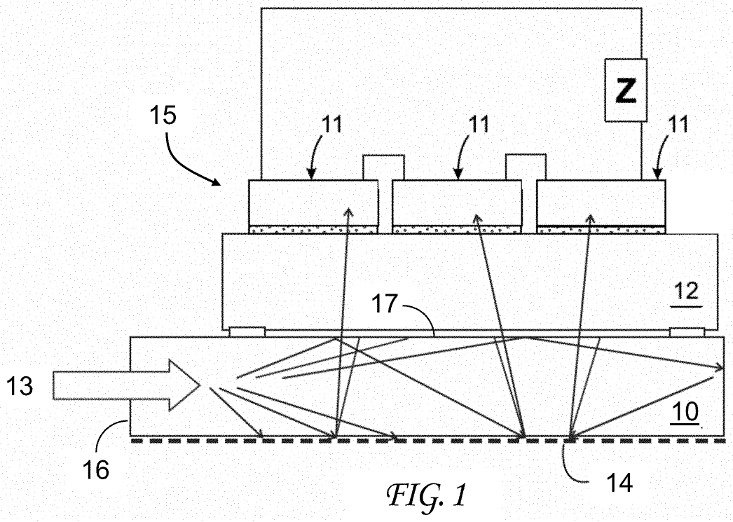

As shown in FIG. 1, the LDP 10 can be edge-illuminated by an array of multimode optical fibers 13 conducting light from a laser diode or LED (not shown) to evenly irradiate the individual PV diodes 11 of a 2D array 15. Each laser diode or LED can provide optical power on the order of hundreds of milliwatts to several watts to the input edge 16 of the LDP 10. The LDP 10 couples the input light from the optical fibers 13, transports the input-coupled light down its length, and output couples reflected light in the direction of the PV array 15 through the top surface 17. The input-coupled light travels in the LDP 10 due to total internal reflection and, due to the presence of micro-optical structures on the bottom surface 14 of the LDP 10, is reflected through the top surface 17 toward the PV array 15. The distribution of the reflected light on the top surface 17 depends on the direction of the incident rays and the details of the microstructure of the bottom surface 14. The irradiated PV array 15 then converts the optical power of the output-coupled light from the LDP 10 to electrical power. The electrical interconnection of the PV diodes 11 combined with the power of the output-coupled light establishes the power output to an attached load Z. The PV array 15 or a transparent spacer plate 12 can be disposed on and separated from the top surface 17 of the LDP 10 by an air gap to provide refractive index contrast with the light guide material. The spacer plate 12 can be made of sapphire, fused silica, or other material transparent at the operation wavelength, for example. The spacer plate 12 can further increase the irradiance uniformity. The invention can conduct optical power of up to 100s of watts. The edge-illuminated LDP 10 is compact and optically efficient in distributing the directional light from the optical fibers 13 uniformly over the large area of the PV array 15 on the top surface in a small form factor. Although the above description contemplates using a spectrally narrow bandwidth light source to uniformly irradiate a PV array, the LDP can be designed to provide uniform irradiation using a broadband light source for other applications.

The LDP design can be analyzed using an optical ray trace/analysis program. The irradiance at the top surface of the LDP can be shown as a false-color intensity pattern. The efficiency can be defined as the ratio of the output power at the PV array to the power at the fiber array input, expressed as a percentage. Both efficiency and uniformity can be improved using a design optimization strategy. See J.-G. Chang and Y.-B. Fang, Optical Engineering 46(4), 043002 (2007). The optimization can include the following novel concepts and methods:

1) tapering LDP thickness;

2) polishing one or more edges at an angle;

3) introducing light to the input edge of the LDP using optical fibers held at an angle;

4) directly fabricating micro-optical structures onto the LDP bottom surface, for example, by etching;

5) using spherical or aspherical micro-optical structures as features to vary the angular distribution of the reflected light (e.g., achieved by cutting, etching, or deposition);

6) using arbitrary shaped micro-optical structures to vary the angular distribution of the reflected light (e.g., achieved by additive manufacturing);

7) distributing these micro-optical structures non-uniformly across the bottom surface of the LDP to improve uniformity and efficiency of irradiation, or to design-in a desired non-uniformity of irradiation;

8) applying a reflective coating to the LDP surface in all regions not directly “covered” by a PV diode (back, sides, and front), thereby “recycling” light back into the LDP where it can reflect again and be output at a PV diode location; and

9) using numeric methods to design complicated non-uniform micro-optical structures for best irradiation efficiency and uniformity.

The LDP can comprise an array of optical fiber light inputs that illuminate the edge of an LDP having a numerical aperture. The fiber ends can be placed perpendicular or tilted at an angle to the input edge, within the acceptance angle of the LDP, and displaced from the input edge to allow the diverging beams to fill the input edge of the LDP. The width and height of the input edge can be varied depending on the number of optical input fibers so as to maximize the light coupled into the LDP. The input edge is optically transparent, while the other three side edges can be bare or specularly reflective. In general, the LDP can be any material that is highly transmissive at the operational wavelength, such as a transparent polymer (e.g., polycarbonate, polypropylene, polystyrene, or polyacrylate), fused silica, glass, or the like, and that has a higher index of refraction than the surrounding medium to enable total internal reflection of the input-coupled light within the LDP. In general, the LDP can be a flat plate, slab, cuboid, or rectangular prism having a bottom surface that is parallel to the top surface, or a wedged plate having a bottom surface that is tilted at an angle to the top surface. In general, the bottom surface can be flat or curved in the longitudinal direction and the tilt angle, position of the tilted surface, and surface curvature can be optimized to provide the desired irradiance pattern at the top surface. The bottom surface can be flat or curved in the transverse direction. The bottom surface comprises a patterned array of micro-optical structures which reflect light in the direction of the top surface of the LDP. The top surface of the LDP is transparent. Reflected light incident on the top surface at less than the critical angle will be transmitted out of the LDP. Light incident on the top surface at greater than the critical angle will be reflected back into the LDP.

The reflecting patterned bottom surface can comprise an array of micro-optical structures with a controlled period and unit shape that can be fabricated by wet chemical etching, reactive ion etching, laser texturing, or other patterning technique. In general, the micro-optical structures can comprise prisms, lenses, grooves, dots, dimples, spherical or aspherical structures, or other optical geometries having dimensions on the order of microns. For example, the reflecting patterned surface can comprise an array of grooves, lenslets, micro-dots, or microprismatic or micropyramidal structures embossed onto or etched into the bottom surface of the LDP. The patterned surface can be tailored so that reflected light is uniformly distributed across the top surface of the LDP. The micro-optical structures can have a periodic pattern whose pitch is different close to the input source plane than at the far edge. The pitch change can be non-linear with position, and can be optimized for uniform irradiance using geometrical optical design software. However, the depth, size, and shape of the micro-optical structures can also be varied to achieve the same effect. For example, the diameter and the depth of the dimples can vary as a function of longitudinal position so as to improve irradiance spatial uniformity on the top surface.

An important consideration for uniform irradiance of the PV array is the effect of coherence in the laser source. Laser light exiting a multimode fiber exhibits speckle, which appears as a granular quality to the illumination pattern. Speckle can adversely affect the performance of series-connected PV arrays in that if the size of the speckle is on the order of a PV element or diode, non-uniform irradiance of PV diodes could exist. A solution is to either eliminate speckle completely or to generate speckle cells much smaller than the PV diode size.

One method to reduce speckle is to introduce a time-varying disturbance into the optical fiber, for example by using an ultrasonic transducer which averages the light over a 40 kHz band width. See I. Fujieda et al., Journal of Display Technology 5(11), 414 (2009). However, this might not eliminate the instantaneous speckle pattern, which could still affect the instantaneous performance of the PV array. Another speckle-reduction method is to use a multiple wavelength laser emitter. A Fabry-Perot diode laser with several longitudinal optical cavity modes operating simultaneously and coupled into a multimode fiber can provide a multiple wavelength emitter. Each of the wavelengths generates its own independent speckle pattern, such that the summed intensity of the multi-wavelength pattern can be much more uniform than that of a single wavelength laser.

### Examples

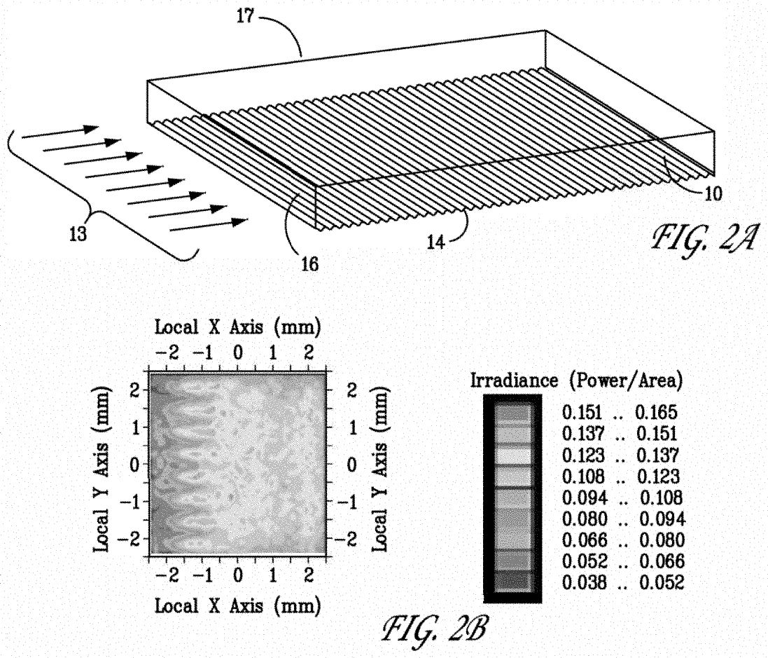

FIG. 2A is a schematic illustration of an exemplary LDP 10 comprising a flat plate with parallel cylindrical grooves in the bottom surface 14 of the plate. The resulting surface undulations are periodic in the longitudinal direction. The exemplary LDP design comprises an array of eight optical fiber light inputs 13 with 105 micrometer core diameter and a numerical aperture of 0.22 that illuminate the input edge 16 of a 5 mm square, 0.5 mm thick fused silica LDP. The fiber ends are displaced 1.1 mm from the input edge 16 of the LDP 10. The input and output surfaces 16 and 17 are bare polished and the other edge surfaces are polished and coated with a high reflectance coating. The bottom surface 14 comprises rows of concave cylinders that was also high reflectance coated. FIG. 2B is a simulation of the resulting irradiance pattern on the top surface 17 of the LDP 10. The LDP is able to distribute the input laser beams. However, the simulated efficiency of this LDP was only 34%. A primary light loss mechanism for this LDP is reflection off the back surface, which reflects the light back out through the input surface.

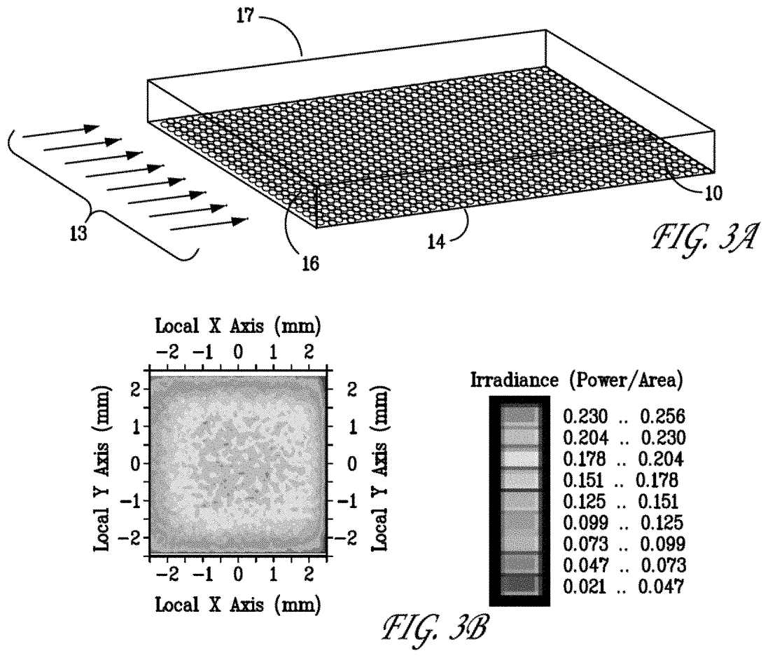

FIG. 3A is a schematic illustration of an exemplary LDP 10 comprising a flat plate with a uniform dimpled etch pattern on the bottom surface 14. The fused silica plate had a cross section of 5 mm×5 mm and a thickness of 0.5 mm. The reflecting pattern on the bottom surface 14 comprised a uniform distribution of dots or dimples, comprising spherical cavities having a radius of 40 μm and an etch depth of 20 μm. The input and output surfaces 16 and 17 were uncoated, and the other surfaces were coated with copper and nickel to maximize reflectance at the design wavelength of 808 nm. FIG. 3B is a simulation showing the computed light distribution at the top surface 17. The simulated efficiency was 50%.

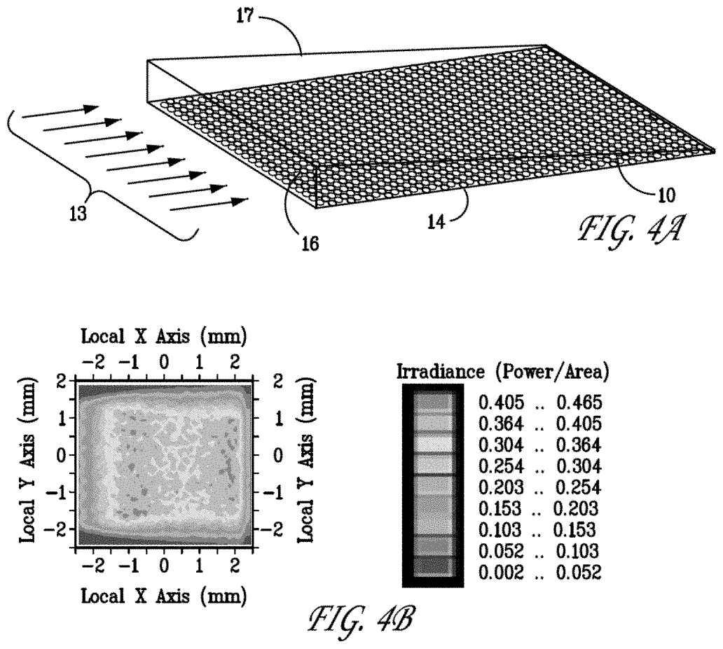

FIG. 4A is a schematic illustration of an exemplary LDP 10 comprising a tapered (wedged) plate. The reflecting patterned bottom surface 14 is flat but tilted at an angle with respect to the top surface 17. This LDP 10 has a uniform distribution of concave dots or dimples on the bottom surface 14 of a wedge-shaped fused silica plate. FIG. 4B shows a simulation of the computed light distribution on the top surface 17 of the LDP 10. The light distribution is more uniform than with a flat plate, and 82.5% total efficiency is achieved. Therefore, wedging the LDP can improve uniformity, but fabrication methods may be more complicated than with flat plates.

The dimple pattern can be varied practically at-will. Dimple spacing can be changed across the plate as can the depth of the etch and the radius of the spherical section. This offers the opportunity to alter the local light scattering strength and customize the irradiance pattern of light coupled out of the top surface. The irradiance pattern can be made flat and uniform or the patterned structure of the bottom surface can be designed to reflect preferentially to provide local maxima and minima on the top surface to fit a device need, such as directing light to several attached photovoltaic cells and not directing light to spaces between photovoltaic cells.

Designing non-uniform micro-structured LDPs can present a challenge. Multiple design metrics need to be evaluated across the LDP region and the “design space” can span variation of 1000s of individual dimples of different size, depth, and even shape. To tackle this design challenge, a genetic algorithm was used based upon an optimization technique capable of handling a large number of continuous as well as discrete variables in the presence of given constraints and 1D and 2D optimization metrics. See D. E. Goldberg, Genetic Algorithms in Search, Optimization and Machine Learning, Addison-Wesley (1989). In the following example, the genetic algorithm was used to optimize an LDP design where dimple diameter was varied in a row-wise fashion. A figure-of-merit (FOM) was used for optimization. The FOM was constructed as a weighted function of multiple criteria including the average optical power at the LDP output, the uniformity of the optical power at the LDP output, and the minimum of the power at the LDP output. The weighting function is designed to reliably quantify the most efficient LDP design with the most uniform power distribution without limiting PV current production due to the small region of low optical intensity.

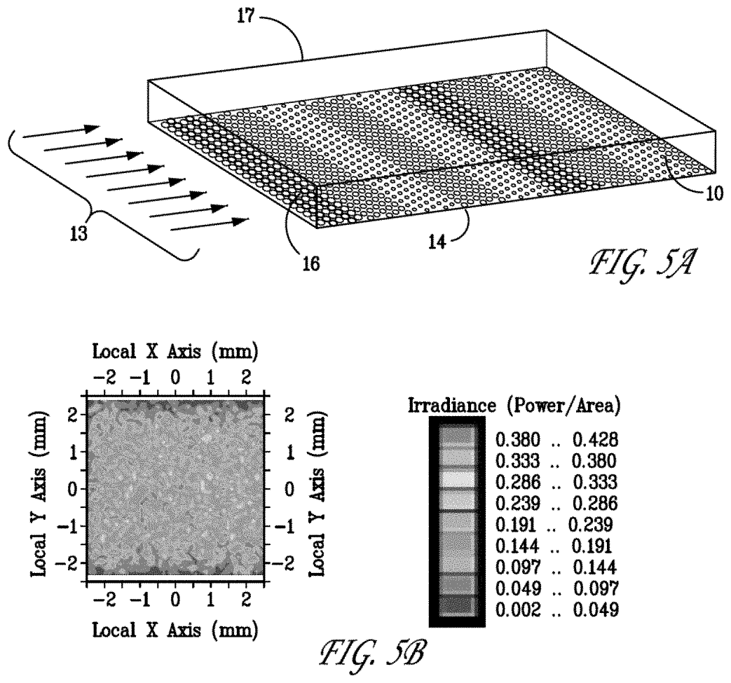

FIG. 5A is a schematic illustration of an exemplary LDP 10 comprising a flat plate with a non-uniform etch pattern on the bottom surface 14 that varied longitudinally in the direction of the input light 13. The plate had a cross section of 5 mm×5 mm and a thickness of 0.5 mm. The input and output surfaces 16 and 17 were uncoated, and the other surfaces were coated with a high reflectance coating. The reflecting pattern was optimized to minimize the difference between the LDP design and a perfect theoretical plate. The design grouped five rows of dimples together in the longitudinal direction and specified the etch pattern aperture and depth for each grouping, as shown in Table 1. Again, the pattern was uniform in the direction perpendicular to the input light, such that transverse uniformity was achieved by the spread of the source via the fiber array. FIG. 5B is a simulation showing the computed output light distribution on the top surface 17.

TABLE 1
Feature dimensions of non-uniform etch pattern

| row number | etch depth (μm) | aperture diameter (μm) |
|---|---|---|
| 1-5 | 17 | 79 |
| 6-10 | 19 | 80 |
| 11-15 | 13 | 66 |
| 16-20 | 8 | 40 |
| 21-25 | 9 | 62 |
| 26-30 | 6 | 48 |
| 31-35 | 7 | 47 |
| 36-40 | 8 | 68 |
| 41-45 | 10 | 77 |
| 46-50 | 11 | 71 |
| 51-55 | 8 | 73 |
| 56-60 | 8 | 64 |
| 61-65 | 5 | 43 |
| 66-70 | 10 | 68 |
| 71-75 | 12 | 65 |
| 76-82 | 13 | 55 |

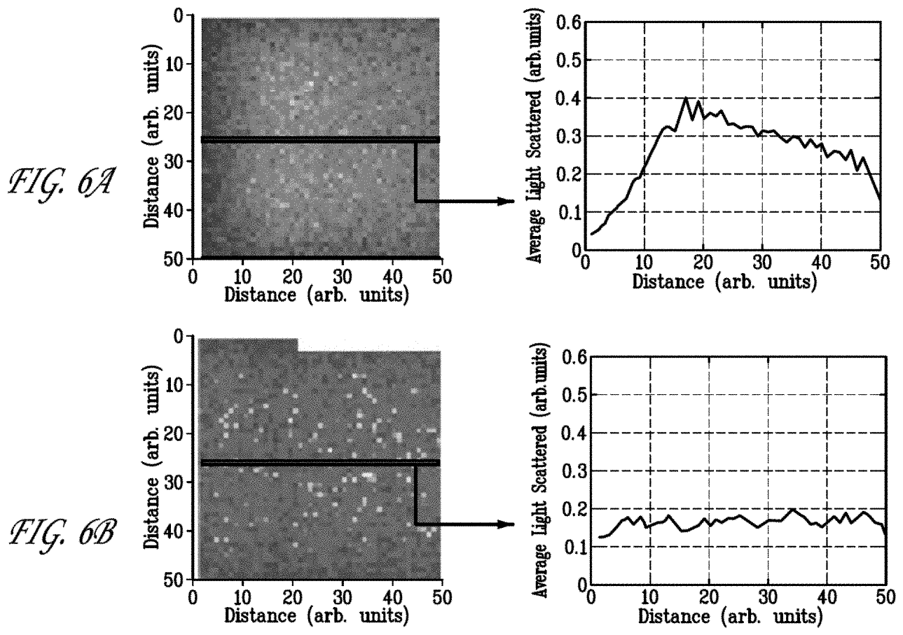

FIGS. 6A and 6B show line outs comparing the uniformity of irradiance of the LDP design shown in FIG. 3A, with an invariant pattern, and the LDP design shown in FIG. 5A, with surface features that varied along the length. The irradiance pattern is much more uniform for the latter design.

### LDP Fabrication

A number of methods for manufacturing the LDP are available. LGPs have been fabricated from PMMA or other polymer resins. A master can be made by processes used in the microlithography industry, and the LDP can then be simply molded or stamped out. However, polymer materials may not be desirable for some applications. If made from a vitreous material, such as glass or fused silica, the features can be etched using well-established processes such as grey-scale lithography. See Z. Cui et al., Proc. SPIE 4984, Micromachining Technology for Micro-Optics and Nano-Optics (2003). Other optical materials, like zinc selenide, can be deposited by chemical vapor deposition on appropriate tooling and used as molds. See M. Kubo and M. Hanabusa, Applied Optics 29(18), 2755 (1990). Alternatively, LDPs can be fabricated using advanced additive manufacturing methods, as will be described below.

The genetic algorithm approach is extremely powerful and capable of creating designs that are not readily fabricated by conventional lithography or micro-machining methods. However, additive manufacturing methods are capable of directly “printing” nearly arbitrary patterns of dimples or any other shape. The limitation is mainly that of the dimensional resolution of the printing tool and the material properties of the deposited material. Recently a tool called the “Nanoscribe” became available with feature size resolution <0.2 um. The printing medium can be a variety of UV-curable print materials such as photoresist. Using this type of additive manufacturing allows for a thin scattering layer of micro-optic features to be printed directly onto the bottom surface of an otherwise flat fused silica plate that can be used as an LDP. Alternatively, the entire LDP can be printed as a monolithic whole. If the 3D printed material is not suited for the application of the LDP (e.g., high temperatures or radiation environments), pattern transfer such as dry plasma etching can be used to transfer the micro-optic shapes onto the surface of, for example, a fused silica blank. Alternatively, the LDP shape can be printed in polymer and then the entire shape can be coated in metal. A selective removal process can then be used to dissolve the polymer to flow out of the interior of the metal leaving only a metal shell to act as the LDP. Such a highly reflective metal surface with the desired micro-optic shapes can provide a nearly ideal LDP with low optical losses and resistance to high and low temperatures and many types of radiation.

The present invention has been described as a light distribution plate for uniform irradiation of compact photovoltaic arrays. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A light distribution plate that is optically transparent at an operational wavelength of input light, has an index of refraction higher than a surrounding medium, and has an optically transparent top surface, a bottom surface comprising a reflecting pattern of micro-optical structures, and at least one side edge, wherein the input light is coupled into the light distribution plate through an optically transparent side edge, the input-coupled light travels in the light distribution plate by total internal reflection, and at least a portion of the input-coupled light is reflected by the micro-optical structures on the bottom surface and coupled out of the top surface.

2. The light distribution plate of claim 1, wherein the light distribution plate comprises a flat plate, slab, cuboid, or rectangular prism.

3. The light distribution plate of claim 1, wherein the light distribution plate comprises a wedged plate having a bottom surface that is tilted with respect to the top surface.

4. The light distribution plate of claim 1, wherein the bottom surface is flat.

5. The light distribution plate of claim 1, wherein the bottom surface is curved.

6. The light distribution plate of claim 1, wherein the light distribution plate comprises a polymer, fused silica, or glass.

7. The light distribution plate of claim 1, wherein at least one of the side edges is reflective.

8. The light distribution plate of claim 1, wherein at least one of the side edges is tilted.

9. The light distribution plate of claim 1, wherein the reflecting micro-optical structures comprises a prism, lens, groove, dot, dimple, cylinder, or spherical or aspherical scattering structure.

10. The light distribution plate of claim 1, wherein the reflecting pattern comprises an array of micro-optical structures that are of uniform size, depth, shape, and spacing.

11. The light distribution plate of claim 1, wherein the reflecting pattern comprises an array of micro-optical structures that have a size, depth, shape, or spacing that is varied to provide a desired irradiation pattern at the top surface.

12. The light distribution plate of claim 1, wherein the reflecting pattern comprises an array of micro-optical structures having a periodic pattern in a longitudinal direction.

13. The light distribution plate of claim 12, wherein a pitch of the periodic pattern is coarser close to the optically transparent side edge of the input-coupled light than at a far edge.

14. The light distribution plate of claim 1, wherein the input-coupled light comprises laser light.

15. The light distribution plate of claim 14, further comprising an ultrasonic transducer for introducing a time-varying disturbance into the at least one optical fiber to reduce speckle in the input-coupled laser light.

16. The light distribution plate of claim 1, wherein the input-coupled light comprises narrow spectral bandwidth light from a light-emitting diode.

17. The light distribution plate of claim 1, wherein the input-coupled light comprises a broadband light source.

18. The light distribution plate of claim 1, further comprising at least one optical fiber for coupling light into the optically transparent side edge.

19. The light distribution plate of claim 18, wherein the at least one optical fiber comprises a multimode fiber.

20. The light distribution plate of claim 1, further comprising an array of photovoltaic diodes disposed on the top surface of the light distribution plate that are irradiated by the output-coupled light.

21. The light distribution plate of claim 20, further comprising a transparent spacer plate disposed between the light distribution plate and the array of photovoltaic diodes.
